(19) United States
(12) Patent Application Publication
(10) Pub. No.: US 2014/0035702 A1
(43) Pub. Date: Feb. 6, 2014

(54) HYBRID FILTER INCLUDING LC- AND MEMS-BASED RESONATORS

(71) Applicants: Justin Phelps Black, Santa Clara, CA (US); Philip Jason Stephanou, Mountain View, CA (US); Jonghae Kim, San Diego, CA (US); Je-Hsiung Jeffrey Lan, San Diego, CA (US); Sang-June Park, San Diego, CA (US); Changhan Hobie Yun, San Diego, CA (US); Chi Shun Lo, San Diego, CA (US); Chengjie Zuo, Santee, CA (US)

(72) Inventors: Justin Phelps Black, Santa Clara, CA (US); Philip Jason Stephanou, Mountain View, CA (US); Jonghae Kim, San Diego, CA (US); Je-Hsiung Jeffrey Lan, San Diego, CA (US); Sang-June Park, San Diego, CA (US); Changhan Hobie Yun, San Diego, CA (US); Chi Shun Lo, San Diego, CA (US); Chengjie Zuo, Santee, CA (US)

(73) Assignee: QUALCOMM MEMS TECHNOLOGIES, INC., San Diego, CA (US)

(21) Appl. No.: 13/563,252

(22) Filed: Jul. 31, 2012

(51) Int. Cl. H03H 9/00; H03H 7/01

(52) U.S. Cl. 333/186; 333/193; 333/187; 333/175

(57) ABSTRACT

This disclosure provides implementations of filters and filter topologies, circuits, structures, devices, apparatus, systems, and related processes. In one aspect, a device includes one or more LC resonant circuit stages. In some implementations, each LC stage includes an inductor and a capacitor. Each LC stage also has a corresponding resonant frequency. The one or more LC stages are arranged to produce an unmodified passband over a range of frequencies having a corresponding bandwidth. One or more microelectromechanical systems (MEMS) resonators are arranged with the one or more LC stages. The one or more MEMS resonators are arranged with the one or more LC stages so as to modify characteristics of the unmodified passband such that the hybrid filter produces a modified passband having a modified bandwidth and one or more other modified band characteristics.

### TECHNICAL FIELD

This disclosure relates generally to signal processing, and more specifically to devices and methods incorporating MEMS resonators for selectively filtering or otherwise processing signals.

### DESCRIPTION OF THE RELATED TECHNOLOGY

Electromechanical systems (EMS) include devices having electrical and mechanical elements, transducers such as actuators and sensors, optical components (including mirrors), and electronics. EMS can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, or other micromachining processes that etch away parts of substrates or deposited material layers, or that add layers to form electrical, mechanical, and electromechanical devices.

Elastic or “acoustic” wave MEMS resonators have been used in filtering applications. Frequency bandpass filters, for example, are utilized in radio architectures employed by wireless devices such as consumer mobile handsets. Contemporary handsets operate across multiple communication standards and multiple frequency bands. These demands have necessitated the integration of multiple filters within the radio-frequency front-end module (RF-FEM) of such handsets or other wireless devices. As the number of cellular bands increases, as the fractional bandwidth of the cellular bands increase, and as the full-duplex band separations decrease, it also is increasingly challenging to meet the insertion loss and selectivity requirements in a low-cost, compact form factor filter.

Conventional solutions such as surface acoustic wave (SAW) filters have had difficulty addressing the higher performance bands, and thin film bulk acoustic resonator (FBAR) solutions, which may offer the requisite performance, command a price premium. In either case, it also is difficult to integrate multiple frequencies on a single substrate. Other examples of conceptual solutions have been proposed to enable higher levels of integration including: contour mode resonators (CMR) having operating frequencies determined by lithographically-defined in-plane dimensions; multi-structural layer FBAR implementations involving shadow masking or buried etch stop layers; or FBAR-like structures topped with lithographically-defined “tuning patterns.” CMRs, for example, can offer multiple frequencies on the same substrate, but, without multiple layers and an improvement in the understanding of the device physics, the fractional bandwidths have been limited to less than approximately 2%. For comparison, typical cellular bands generally require fractional bandwidths of 3% or greater.

Additionally, in conventional acoustic wave filters the bandwidth is directly proportional to the resonator's coefficient of electromechanical coupling, kₜ², (or equivalently the ratio of the motional to fixed capacitance Cₘ /C_{O}). Because CMR topologies to date exhibit lower coupling than some FBAR and SAW devices, achieving wide fractional bandwidth filters using CMRs has been challenging. Lastly, passives-on-glass (POG)-based inductor-capacitor (LC) filters offer wide fractional bandwidths with low insertion loss, but the roll-off and selectivity is fundamentally limited, especially when a compact form factor is required.

### SUMMARY

The structures, devices, apparatus, systems, and processes of the disclosure each have several innovative aspects, no single one of which is solely responsible for the desirable attributes disclosed herein.

Disclosed are example implementations of hybrid filter topologies that include both inductor-capacitor (LC) resonant circuit stages as well as MEMS resonators. Devices, apparatus, systems, and related fabrication processes and techniques also are disclosed.

According to one innovative aspect of the subject matter described in this disclosure, a device includes one or more LC resonant circuit stages. In some implementations, each LC stage includes an inductor and a capacitor. Each LC stage also has a corresponding resonant frequency. The one or more LC stages are arranged to produce an unmodified passband over a range of frequencies having a corresponding bandwidth. One or more microelectromechanical systems (MEMS) resonators are arranged with the one or more LC stages. The one or more MEMS resonators are arranged with the one or more LC stages so as to modify characteristics of the unmodified passband such that the hybrid filter produces a modified passband having a modified bandwidth and one or more other modified band characteristics.

In some implementations, the one or more other modified band characteristics include one or more of the following: sharper roll-off at one or more edges of the modified passband; a smaller shape factor relative to the unmodified passband; and a notch or stopband in a portion of the frequencies in the range of frequencies corresponding to the unmodified passband. In some implementations, the modified bandwidth is a narrower bandwidth than the unmodified bandwidth. In some implementations, the modified passband has a larger (wider) fractional bandwidth than the unmodified passband.

In some implementations, the one or more LC stages include two or more series LC stages arranged in series with one another. In some such implementations, the one or more MEMS resonators include one or more shunt MEMS resonators each arranged to shunt current between a set of two adjacent series LC stages to ground. In some such implementations, the one or more LC stages include one or more shunt LC stages each arranged between two adjacent series LC stages and arranged to shunt current between the two series LC stages to ground; and one or more of the shunt MEMS resonators are arranged in parallel with one or more of the shunt LC stages. In some such implementations, the one or more MEMS resonators include one or more series MEMS resonators each arranged in series with one another or with one or more of the series LC stages. In some such implementations, the device further includes at least one shunt MEMS resonator arranged to shunt current between a series LC stage and an adjacent or neighboring series MEMS resonator to ground.

In some other implementations, the one or more MEMS resonators include two or more series MEMS resonators arranged in series with one another. In some such implementations, the one or more MEMS resonators include one or more shunt MEMS resonators each arranged to shunt current between a set of two adjacent MEMS resonators to ground. In some such implementations, the one or more LC stages include one or more shunt LC stages each arranged to shunt current between a set of two adjacent series MEMS resonators to ground; and one or more of the shunt MEMS resonators are arranged in parallel with one or more of the shunt LC stages. In some such implementations, the one or more LC stages include one or more series LC stages each arranged in series with one another or with one or more of the series MEMS resonators. In some such implementations, the device further includes at least one shunt MEMS resonator arranged to shunt current between a series LC stage and an adjacent or neighboring series MEMS resonator to ground.

In some implementations, one or more of the MEMS resonators have different resonant frequencies than other ones of the MEMS resonators. In some implementations, one or more of the MEMS resonators are elastic or acoustic resonators. For example, one or more of the MEMS resonators can be contour-mode resonators (CMRs). In some implementations, one or more of the MEMS resonators are thin film bulk acoustic resonators (FBARs). In some implementations, both the LC stages and the MEMS resonators are fabricated on a single substrate.

According to another innovative aspect of the subject matter described in this disclosure, a device includes one or more LC resonating means. In some implementations, each LC resonating means includes an inducting means and a capacitive means. In some implementations, each LC resonating means has a corresponding resonant frequency. The one or more LC resonating means are arranged to produce an unmodified passband over a range of frequencies having a corresponding bandwidth. One or more MEMS-based resonating means are arranged with the one or more LC resonating means. The one or more MEMS-based resonating means are arranged with the one or more LC resonating means so as to modify characteristics of the unmodified passband such that the hybrid filter device produces a modified passband having a modified bandwidth and one or more other modified band characteristics.

In some implementations, the one or more MEMS-based resonating means include two or more series MEMS-based resonating means arranged in series with one another or with an LC resonating means. In some implementations, the one or more MEMS-based resonating means include one or more shunt MEMS-based resonating means each arranged to shunt current between two MEMS-based resonating means or between two LC resonating means or between a MEMS-based resonating means and an LC resonating means.

In some implementations, the LC resonating means and the MEMS-based resonating means are fabricated on a single substrate. Additionally, in some implementations, the modified passband has a larger fractional bandwidth than the unmodified passband.

Details of one or more implementations of the subject matter described in this specification are set forth in the accompanying drawings and the description below. Although the examples provided in this disclosure may be described in terms of EMS and MEMS-based displays, the concepts provided herein may apply to other types of displays, such as liquid crystal displays (LCDs), organic light-emitting diode (OLED) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example 4^{th}-order binomial filter.

FIG. 2 shows an example implementation of a hybrid 4^{th}-order binomial filter loaded with a MEMS resonator.

FIG. 3 shows a plot depicting example frequency responses for the binomial filters depicted in FIG. 1 and in FIG. 2.

FIG. 4A shows a plot depicting a pole-zero map of the binomial filter depicted in FIG. 1.

FIG. 4B shows a plot depicting a pole-zero map of the binomial filter depicted in FIG. 2.

FIG. 5 shows plots depicting example frequency responses for the 4^{th}-order binomial filter depicted in FIG. 1 and a hybrid 4^{th}-order binomial filter loaded with 32 Shunt MEMS resonators.

FIG. 6 shows an example of a 5^{th}-order Chebyshev filter.

FIG. 7 shows an example implementation of a hybrid 5^{th}-order Chebyshev filter loaded with a plurality of MEMS resonators.

FIG. 8 shows plots depicting example frequency responses for the 5^{th}-order Chebyshev filter depicted in FIG. 6 and the hybrid 5^{th}-order Chebyshev filter depicted in FIG. 7.

FIG. 9 shows an example of a flow diagram illustrating a process for forming a combined resonator and passive circuit component device.

FIGS. 10A-10F show examples of cross-sectional schematic illustrations of stages of combined resonator and passive circuit component device fabrication in accordance with a process, for instance, as represented in FIG. 9.

FIG. 10G shows an example of a top-down view of a combined resonator and passive circuit component device, for instance, as represented in FIG. 10F.

FIG. 11A is an isometric view illustration depicting two adjacent interferometric modulator (IMOD) display elements in a series or array of display elements of an IMOD display device.

FIG. 11B is a system block diagram illustrating an electronic device incorporating an IMOD-based display including a three element by three element array of IMOD display elements.

FIGS. 12A and 12B are system block diagrams illustrating a display device that includes a plurality of IMOD display elements.

Like reference numbers and designations in the various drawings indicate like elements.

### DETAILED DESCRIPTION

The following detailed description is directed to certain implementations for the purposes of describing the innovative aspects. However, the teachings herein can be applied and implemented in a multitude of different ways.

The disclosed implementations include examples of filters or filtering topologies, circuits, or modules (hereinafter collectively referred to as “filters”). Related apparatus, systems, and fabrication processes and techniques are also disclosed. Some implementations specifically relate to electronic filters; that is, electronic circuits that perform signal processing functions including filtering operations. Some implementations more specifically relate to electronic filters employing both conventional passive reactive filter elements as well as microelectromechanical systems (MEMS)-based resonators. Some implementations combine the strengths of classic inductor-capacitor (LC) filter topologies with advantages of MEMS resonators, including high quality-factor (Q).

In some implementations, the MEMS resonators modify the passband, bandwidth, or other band characteristics that would otherwise be produced by the LC filter topology without the MEMS resonators. That is, in other words, the MEMS resonators can be said to modify characteristics of the unmodified passband (the passband and band characteristics that would be produced without the MEMS resonators) so as to produce a modified passband having a modified bandwidth or one or more other modified band characteristics. In some implementations, the modified passband characteristics, including the modified bandwidth or the one or more other modified band characteristics, are attributable at least in part to the higher Q of the MEMS resonators as compared with the LC stages.

Particular implementations of the subject matter described in this disclosure can be implemented to realize one or more of the following potential advantages. In some implementations, the bandwidth and insertion loss of the filter can be decoupled from the coefficient of electromechanical coupling kₜ² of the MEMS resonators. Additional technical advantages include one or more of the following: the ability to fabricate both the LC stages and the MEMS resonators on a single, miniaturized substrate; the ability to fabricate filters at multiple frequencies; the ability to fabricate filters having wide fractional bandwidths, sharp roll-off, high selectivity, and low insertion loss; and the ability to integrate passives-on-glass (POG) networks to match to external impedances.

Some example implementations utilize elastic wave or “acoustic” MEMS resonators. Some such implementations utilize piezoelectric-based MEMS resonators, and in even more particular implementations, aluminum nitride (AlN) contour mode resonators (CMRs), to achieve wide fractional bandwidth—in some implementations greater than 12%, low-insertion loss, and high selectivity. In some implementations, other MEMS resonators such as other CMRs, SAW filters, BAW filters, FBARs, or quartz-based filters can be used. In some other implementations, non-piezoelectric MEMS resonators may be suitable. In some such implementations, the MEMS resonators may operate according to other electromechanical transduction mechanisms or to non-electromechanical transduction mechanisms such as electrostatic transduction.

Passive reactive filter elements include inductors, which at a basic level conduct low-frequency signals and block high-frequency signals, and capacitors, which at a basic level conduct high-frequency signals and block low-frequency signals. In some implementations, electronic filters also include resistors to determine the time-constants of the circuit, which influence the frequencies to which the circuit responds. Each combination or set of an inductor and a capacitor can be considered a single LC tuned-circuit, LC tank, LC resonator, or LC stage (hereinafter collectively referred to as an “LC stage”). Each LC stage generally has a resonant frequency. The number of LC stages generally determines the order of the filter. Some basic LC stage topologies include the L-section (or L filter), C-section, the T-section or (T filter), and the 7C-section (or π filter). Generally, LC stages or their constituent inductor and capacitor elements can be arranged in a multitude of electronic filter topologies according to the transfer function desired. For example, LC stages can be arranged in unbalanced topologies such as, for example, L-sections, T-sections, and π-sections. A multitude of LC stages also can be combined to produce an unbalanced ladder network. LC stages also can be arranged in balanced topologies such as, for example, C-sections, H-sections, Box sections, and balanced ladder networks.

Some implementations relate to LC topologies arranged as linear filters or arranged to perform as substantially linear filters. Linear filters in the time domain process time-varying input signals to produce output signals subject to the constraint of linearity. Some implementations relate to LC topologies arranged as linear time-invariant (LTI) filters or arranged to perform as substantially LTI filters, such as an analog infinite impulse response (IIR) LTI filter. Some simple examples of such filters include low-pass filters, high-pass filters, band-pass filters, band-stop filters, notch filters, all-pass filters, equalization filters, among others. As described above, the number of LC stages generally gives the order N of the filter. In mathematical terms, the order N describes the order of the rational function describing the frequency response of the filter. An N^{th} order electronic filter generally requires N reactive elements (where each reactive element can be an LC stage or other LC element or an individual inductor or an individual capacitor depending upon the arrangement).

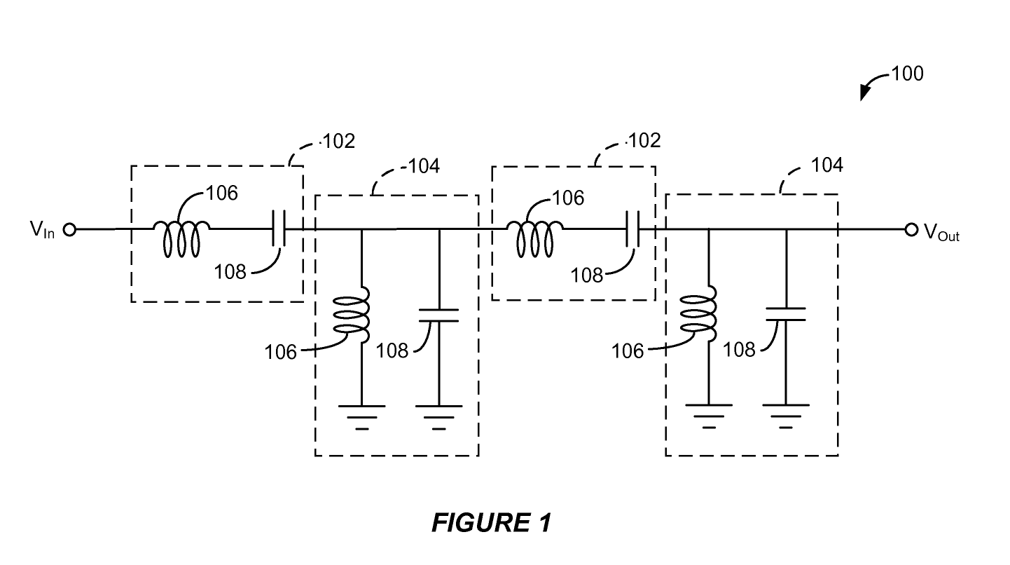

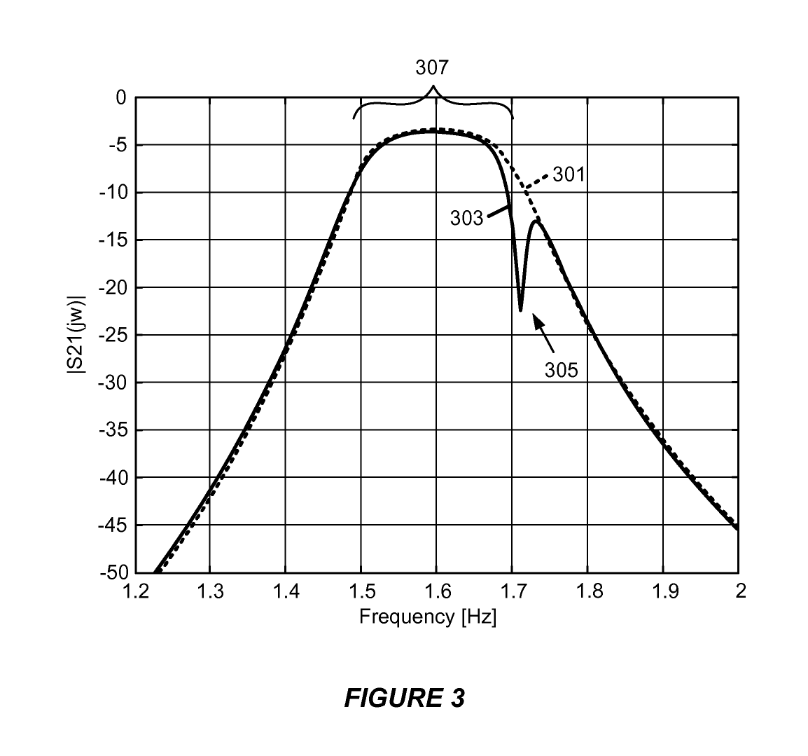

One example of an electronic filter is a binomial filter. FIG. 1 shows an example 4^{th}-order binomial filter 100. The binomial filter 100 includes four LC stages including two series LC stages 102 and two shunt (e.g., shunting current to ground) LC stages 104. Each LC stage includes an inductor 106 and a capacitor 108. In the depicted example, the first LC stage 102 is coupled to receive an input signal V_{In}. Each shunt LC stage 104 is coupled to ground. An output of the binomial filter 100 is coupled to output a signal V_{Out}. An example frequency response for the binomial filter 100 depicted in FIG. 1 is depicted in FIG. 3, described later.

As described above, some implementations relate to “hybrid” filters that combine conventional reactive filter elements, including inductors and capacitors, with MEMS resonators. In some implementations, the hybrid electronic filters utilize both conventional reactive filter elements arranged in, or arranged similar to, traditional topologies, as well as MEMS resonators arranged in conjunction with the traditional or other LC filter topologies. Some implementations utilize LC resonator circuits or stages arranged in traditional filter topologies, such as those described above, in conjunction with MEMS resonators strategically arranged with the LC stages. For example, the traditional LC topologies can include N^{th}-order binomial filters, N^{th}-order Chebyshev type-1 filters, N^{th}-order Chebyshev type-2 filters, and N^{th}-order Elliptic filters, among other possibilities. For example, the binomial filter is designed to have a flat frequency response in the passband and is also referred to, for this reason, as a maximally flat magnitude filter. Typically, binomial filters are implemented according to the Cauer topology. In such a topology, the filter is implemented with series inductors and shunt capacitors. The Chebyshev filters have steeper roll-off than binomial filters. But Chebyshev type-1 filters have more passband ripple while Chebyshev type-2 filters have more stopband ripple. An elliptic filter, also referred to as a Cauer filter, is a filter having equalized ripple behavior in both the passband and the stopband.

Some implementations combine the strengths of traditional LC filter topologies with advantages of MEMS resonators, including high Q factor. In some implementations, the MEMS resonators and the LC stages are fabricated on a single substrate as opposed to in the form of discrete components assembled in system-in-package (SIP) designs or other design packages. This integration can permit compact form factors as well.

In some implementations, the MEMS resonators modify the passband, bandwidth, or other band characteristics that would otherwise be produced by the LC filter topology without the MEMS resonators. That is, in other words, the MEMS resonators can be said to modify characteristics of the unmodified passband (the passband and band characteristics that would be produced without the MEMS resonators) so as to produce a modified passband having a modified bandwidth or one or more other modified band characteristics. In some implementations, the one or more other modified band characteristics include sharper roll-off at one or more edges of the modified passband. In some implementations, the one or more other modified band characteristics include a smaller shape factor in the modified passband relative to the unmodified passband. In some implementations, the one or more other modified band characteristics include a notch or stopband not present in the unmodified passband. In some implementations, the modified bandwidth is narrower than the unmodified bandwidth. In some implementations, the modified passband has a larger (wider) fractional bandwidth than the fractional bandwidth that would be present in the unmodified passband. In some implementations, the modified passband characteristics, including the modified bandwidth or the one or more other modified band characteristics, are attributable at least in part to the higher Q factor of the MEMS resonators as compared with the LC stages.

An advantage of particular implementations is that the bandwidth and insertion loss of the filter can be decoupled from the coefficient of electromechanical coupling kₜ² of the MEMS resonators. Additional technical advantages include one or more of the following: the ability to fabricate both the LC stages and the MEMS resonators on a single, miniaturized substrate; the ability to fabricate filters at multiple frequencies; the ability to fabricate filters having wide fractional bandwidths, sharp roll-off, high selectivity, and low insertion loss; and the ability to integrate passives-on-glass (POG) networks to match to external impedances.

In some implementations, the example hybrid filters include shunt and series MEMS resonators that are selectively introduced to the LC filter topology to add multiple zeroes in the transfer function. In some implementations, the MEMS resonators are arranged with traditional LC filter topologies such that the MEMS resonators synthesize stopband zeros. In some implementations, the MEMS resonators are designed and arranged such that the zeroes are placed close to the edge of the passband to provide sharp roll-off. In some implementations, the classic LC filter architecture synthesizes a passband with large bandwidth, and the MEMS resonators modify the passband by providing sharper roll-off at the band edges or a notch or stopband within the passband.

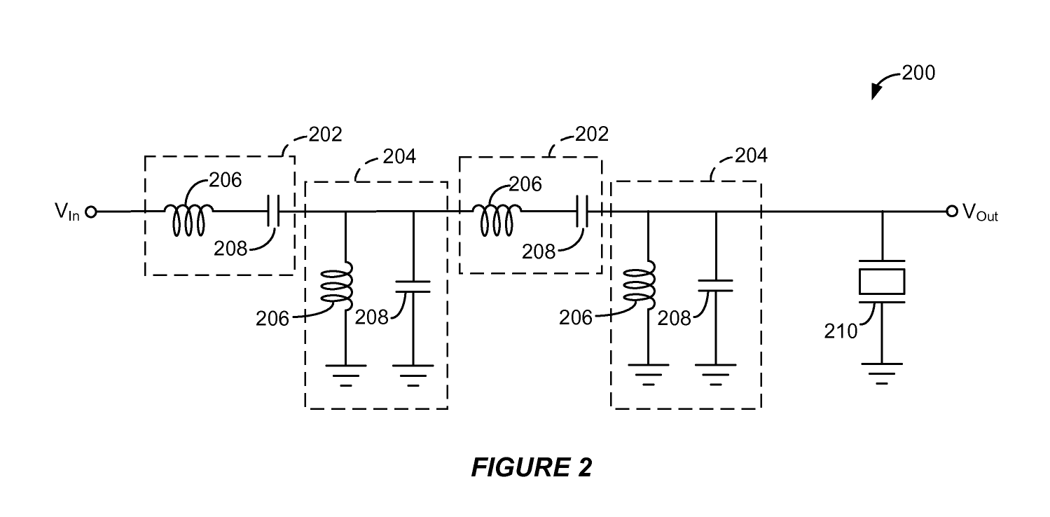

FIG. 2 shows an example implementation of a hybrid 4^{th}-order binomial filter 200 loaded with a MEMS resonator. The binomial filter 200 includes four LC stages including two series LC stages 202 and two shunt (e.g., shunting current to ground) LC stages 204, arranged the same as or similar to the arrangement of the binomial filter 100 depicted in FIG. 1. Each LC stage includes an inductor 206 and a capacitor 208. In the depicted example, the first LC stage 202 is coupled to receive an input signal V_{In}. Each shunt LC stage 204 is coupled to ground. An output of the binomial filter 200 is coupled to the MEMS resonator 210 which is then coupled to output a signal V_{Out}. FIG. 3 shows plots 301 and 303 depicting example frequency responses for the binomial filters 100 and 200 depicted in FIG. 1 and in FIG. 2, respectively.

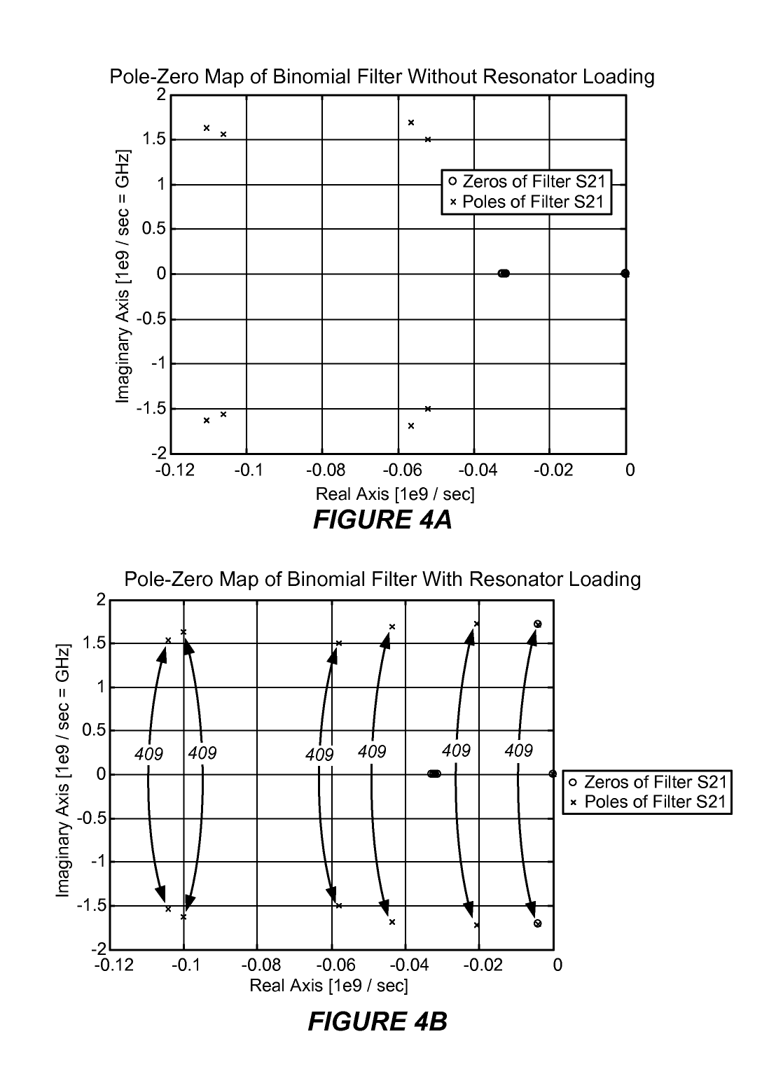

As shown in FIG. 3, Error! Reference source not found.loading a 4^{th}-rder LC binomial filter 200 with a MEMS resonator 210 can introduce a notch 305 in the passband 307. FIG. 4A shows a plot depicting a pole-zero map of the binomial filter 100 depicted in FIG. 1. FIG. 4B shows a plot depicting a pole-zero map of the binomial filter 200 depicted in FIG. 2. FIG. 4B, when compared with FIG. 4A, shows how the MEMS resonator 210 introduces new complex pole pairs or zero pairs 409 and shifts the unloaded filter pole-zero positions. Each pole pair or zero pair refers to a set of two poles or a set of two zeros with the same real component but opposite imaginary components. These resonator complex zeros introduce the notch 305 in the S₂₁ plot shown in FIG. 3.

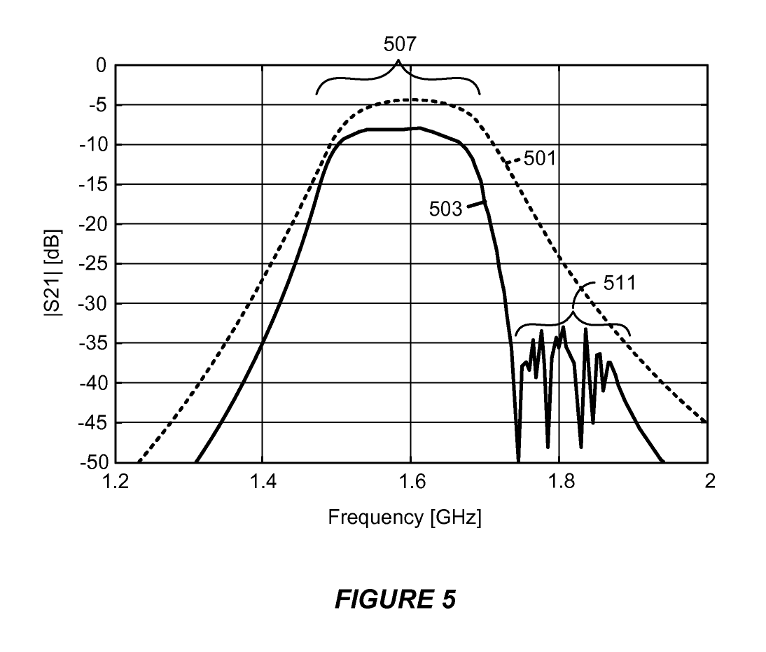

In other implementations, the hybrid filters can be loaded with arrays of MEMS resonators 210. For example, the MEMS resonator 210 depicted in FIG. 2 can be replaced with an array of MEMS resonators, for example, an array of 32 shunt MEMS resonators 210. In some other implementations, hybrid filters can be loaded with one or more arrays having different numbers of shunt MEMS resonators or with one or more arrays of series MEMS resonators. The 32 shunt MEMS resonators 210 can be selected to have multiple offset frequencies. FIG. 5 shows plots 501 and 503 depicting example frequency responses for the 4^{th}-order binomial filter 100 depicted in FIG. 1 and a hybrid 4^{th}-order binomial filter loaded with 32 shunt MEMS resonators 210, respectively. As shown, rather than a notch 305, the passband 507 now has a steeper (sharper) roll-off and a new stopband 511. In some implementations, a purpose of the 32 shunt resonators is to introduce transmission zeros in the filter passband and improve roll-off or selectivity. For example, the passband 507 achieves 28 dB of rejection at 50 MHz offset at only 3 dB of insertion loss compared to the 150 MHz offset of the unloaded LC filter 100. In an example, the motional impedances of the MEMS resonators can range from 25 to 50 ohms (Ω). The static capacitance, Cₒ, can be approximately 400 femtofarads (fF), the electromechanical coupling kₜ² can be less than approximately 2.1%, and the figure-of-merit (FOM) can be approximately 10. In some implementations, this suggests that while a relatively large number of MEMS resonators may be used, each device could be quite small. That is, given the nature of new fabrication processes and arrays of resonators demonstrated to date, it would be expected such a device would require a small substrate area, such as that comparable to other existing solutions.

In some implementations, one or more MEMS resonators, or arrays of two or more MEMS resonators, are selectively fabricated and interspersed throughout an LC topology, such as between series LC stages and parallel to shunt LC stages. In some implementations, it can generally be desirable to minimize the number of the series and shunt MEMS resonators while achieving the desired transfer function and consequently, the desired modified passband, bandwidth, or other modified band characteristics. In some implementations, it can generally be desirable that there is symmetry with respect to the number and layout of the MEMS resonators amongst the LC stages. Additionally, in some implementations, all the series MEMS resonators have the same resonant frequency, while, in some implementations, all the shunt MEMS resonators have the same resonant frequency, which may or may not be the same as the resonant frequencies of the series MEMS resonators. In various implementations, the MEMS resonators can be designed, sized, arranged, positioned, or otherwise configured based on theoretical techniques or based on empirical techniques.

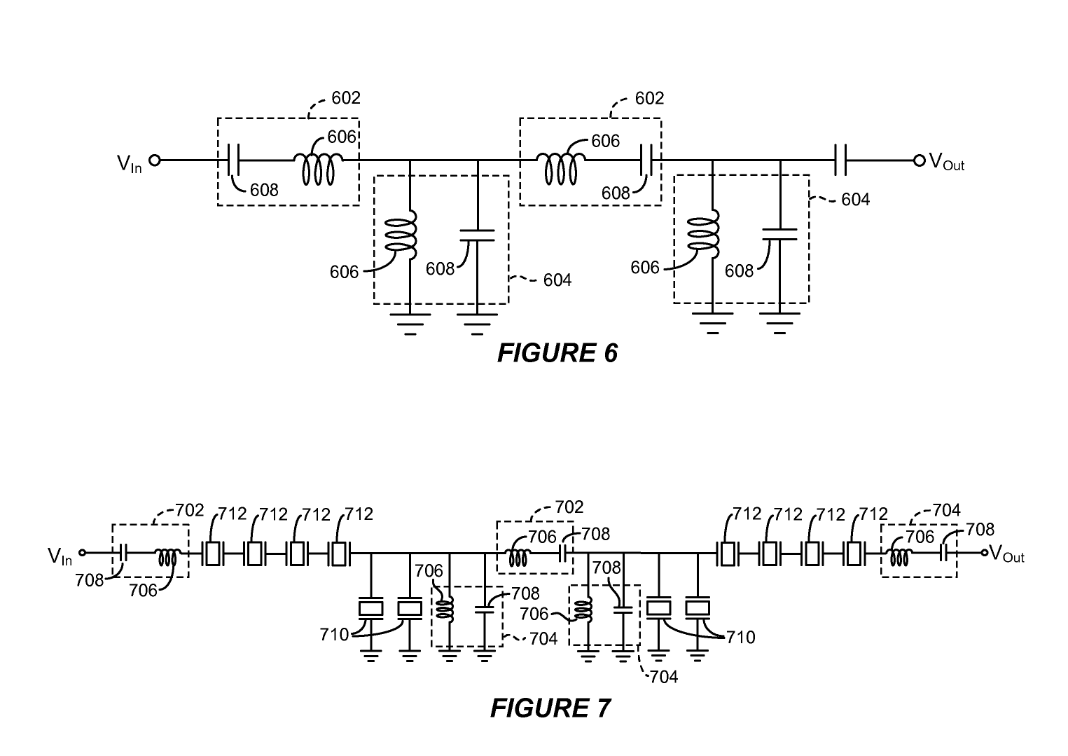

For example, FIG. 6 shows an example of a 5^{th}-order Chebyshev filter 600. As shown, the 5^{th}-order Chebyshev filter 600 includes five LC stages including three series LC stages 602 and two shunt LC stages 604 including inductors 606 and capacitors 608. FIG. 7 shows an example implementation of a hybrid 5^{th}-order Chebyshev filter 700 loaded with a plurality of MEMS resonators. As shown, the hybrid 5^{th}-order Chebyshev filter 700 also includes five LC stages including three series LC stages 702 and two shunt LC stages 704 including inductors 706 and capacitors 708. The plurality of MEMS resonators can include a plurality of arrays of MEMS resonators and can include a plurality of shunt MEMS resonators 710 and a plurality of series MEMS resonators 712. For example, in the implementation depicted in FIG. 7, the hybrid 5^{th}-order Chebyshev filter 700 includes eight total series MEMS resonators: four series MEMS resonators 712 arranged between each pair of adjacent series LC stages 702. In this implementations, the hybrid 5^{th}-order Chebyshev filter 700 also includes four total shunt MEMS resonators 710: two shunt MEMS resonators 710 arranged parallel to each of the shunt LC stages 704.

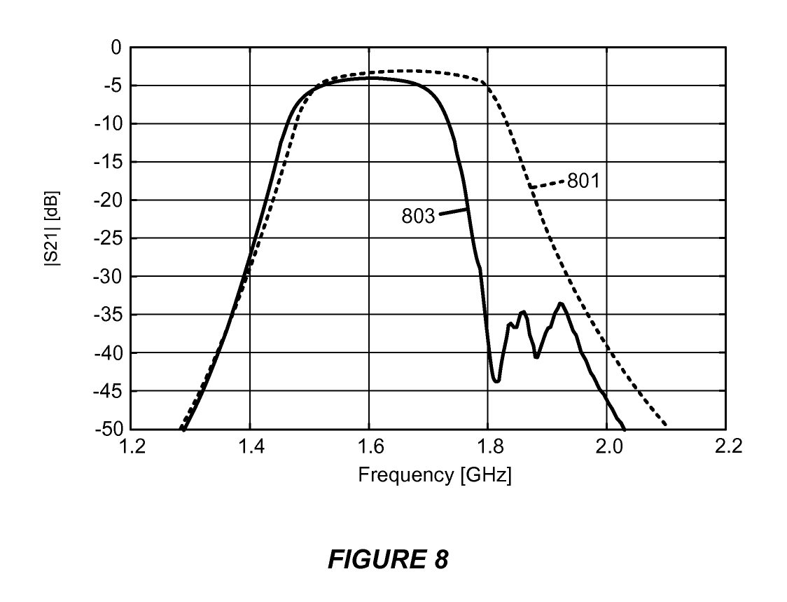

FIG. 8 shows plots depicting example frequency responses for the 5^{th}-order Chebyshev filter depicted in FIG. 6 and the hybrid 5^{th}-order Chebyshev filter depicted in FIG. 7. As shown, loading the LC stages 702 and 704 with eight series MEMS resonators 712 and four shunt MEMS resonators can achieve 240 MHz of bandwidth, 4 dB of insertion loss, and, at the upper skirt, 30 dB of selectivity at a 75 MHz offset (50 S2 termination). In this example implementation, the resonators have an electromagnetic coupling kₜ² of 1.5%, motional impedances greater than 25 S2, series and parallel Q factors of 110 and 300, respectively, and a clamped capacitance Cₒ of 1.5 picofarads (pF). The large clamped capacitance, which is effectively absorbed into the series LC stages 702, also can be significantly reduced through further optimization. In some example applications, the LC stages can utilize inductors ranging from approximately 0.6 to 52 nano-Henries (nH) with Q factors of up to 50 at 1.8 GHz.

In some other implementations, with the use of more sophisticated methods, significant improvements might be expected in insertion loss and roll-off using topologies requiring fewer LC stages and MEMS resonators such as CMRs. In some implementations, hybrid LC and MEMS resonator filters can achieve 40+ dB of rejection at 50 MHz offsets with 100's of MHz of bandwidth by employing CMRs with coupling kₜ² of 1% and FOM of 10.

Additionally, other optimizations can be achieved by carefully selecting an appropriate combination of not only the number and layout of MEMS resonators, but also the type of MEMS resonators used, such as CMR, FBAR, BAW, SAW, among others, and the configuration (e.g., size and design) and material properties of the selected MEMS resonators (e.g., AN, PZT, ZnO, among other suitable materials). Various examples of suitable MEMS resonators and methods of making the same are described in U.S. patent application Ser. No. 13/094,687 (Attorney Docket Number QUALP036) filed Apr. 26, 2011 on behalf of Lan, et al. and entitled “PIEZOELECTRIC RESONATORS AND FABRICATION PROCESSES,” which is hereby incorporated by reference.

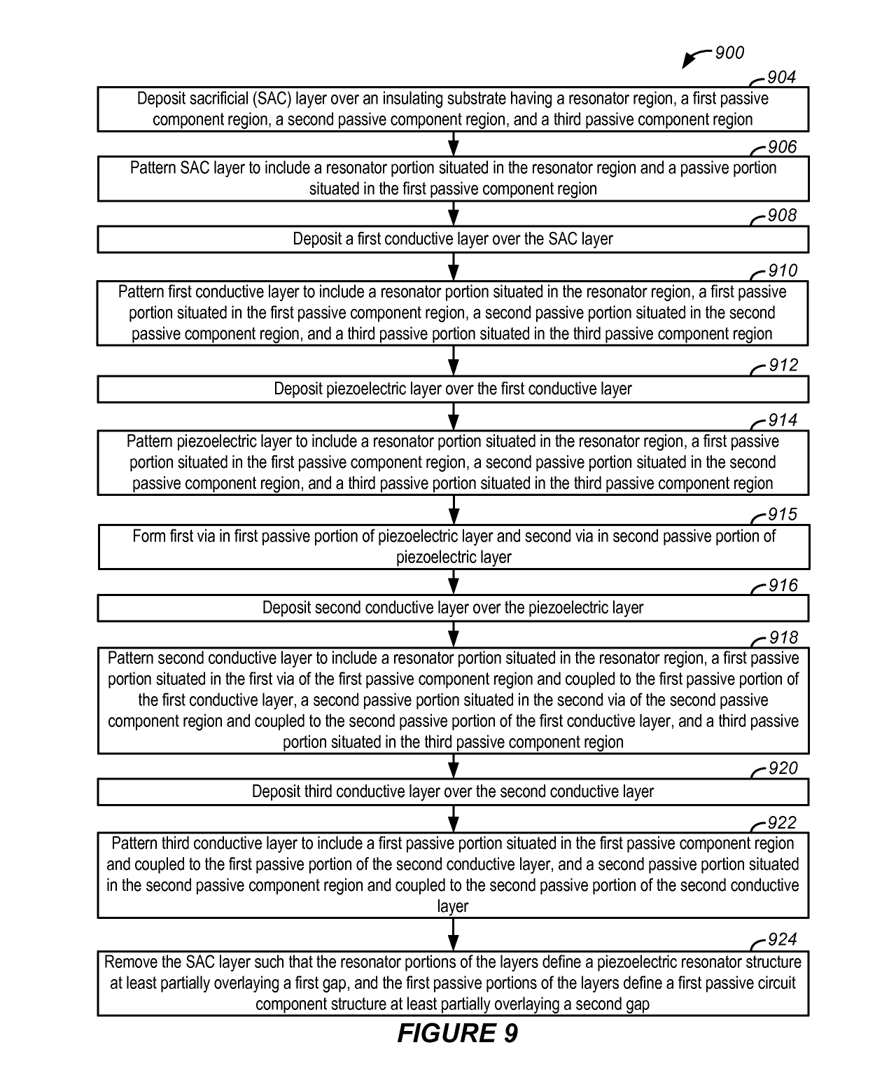

As described above, in some implementations, the MEMS resonators and the LC stages are fabricated on or in a single substrate as opposed to in the form of discrete components assembled in system-in-package (SIP) designs or other design packages. Various examples of suitable MEMS resonators and passive components and methods of making the same on the same substrate are described in U.S. patent application Ser. No. 13/295,955 (Attorney Docket Number QUALP059A/102411U1) filed Nov. 14, 2011 on behalf of Zuo, et al. and entitled “COMBINED RESONATORS AND PASSIVE CIRCUIT COMPONENTS FOR FILTER PASSBAND FLATTENING,” which is hereby incorporated by reference. For example, FIG. 9 shows an example of a flow diagram illustrating a process for forming a combined resonator and passive circuit component device. Such a process or a similar process can be used to form any of the hybrid filters and devices described above with reference to FIGS. 2 and 7.

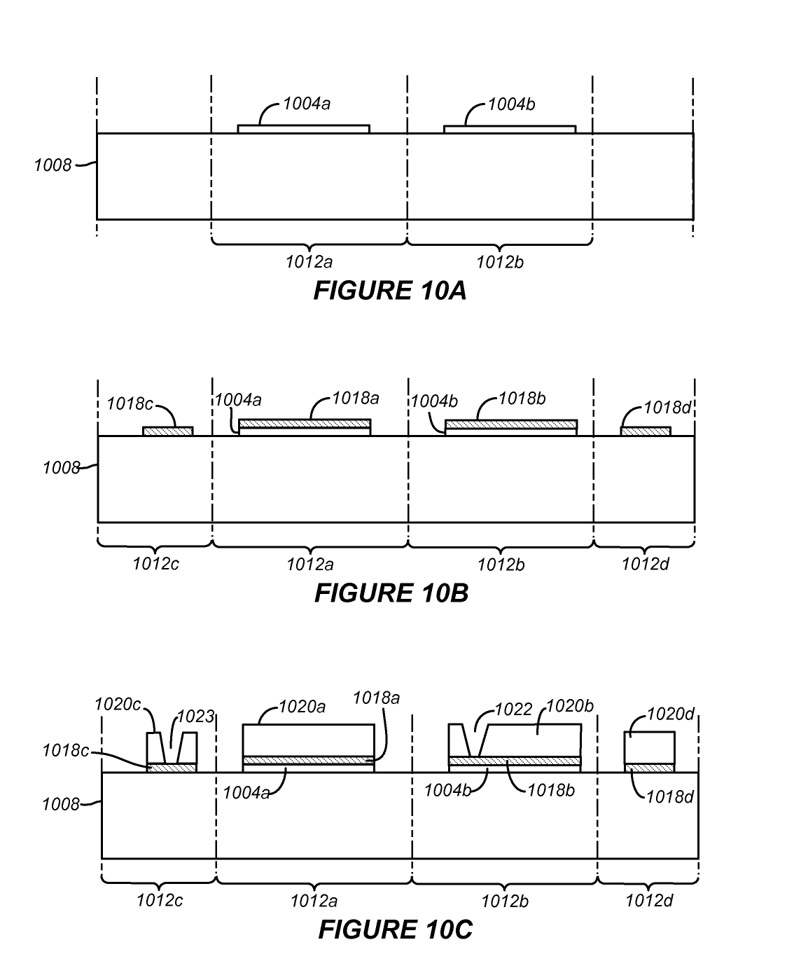

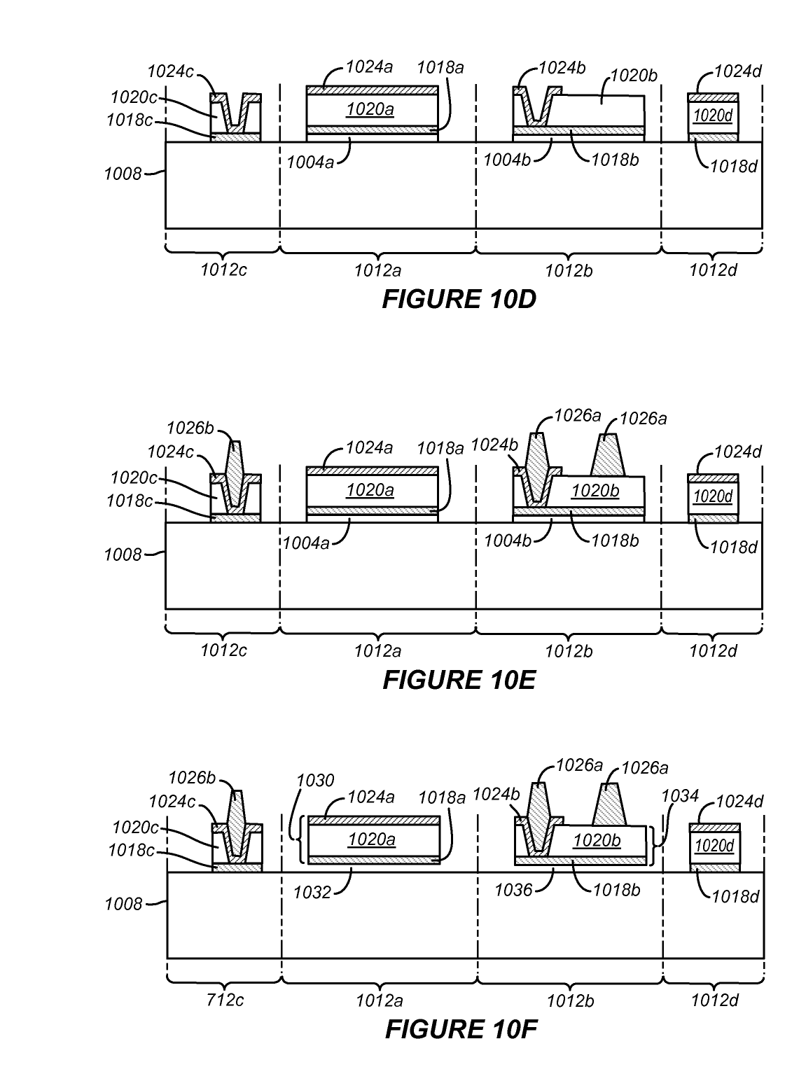

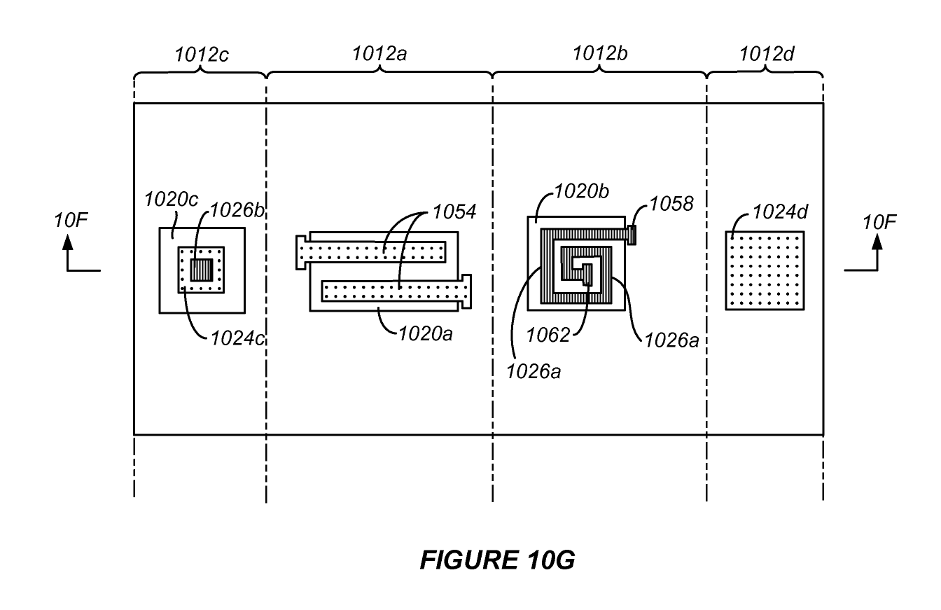

FIGS. 10A-10F show examples of cross-sectional schematic illustrations of stages of combined resonator and passive circuit component device fabrication in accordance with a process, for instance, as represented in FIG. 9. In FIG. 9, the process 900 begins in blocks 904 and 906 in which a SAC layer 1004 is deposited over a substrate 1008 and patterned in a resonator region 1012a and a passive component region 1012b, as described above, and as shown in FIG. 10A. In block 908 of FIG. 9, a first conductive layer 1018 is deposited over SAC layer 1004, as shown in FIG. 10B. In this example, in block 910, a first conductive layer 1018 is patterned to define a resonator portion 1018a situated in the resonator region 1012a, a first passive portion 1018b situated in the first passive component region 1012b, a second passive portion 1018c situated in a second passive component region 1012c, and a third passive portion 1018d situated in a third passive component region 1012d, as shown in FIG. 10B.

In block 912 of FIG. 9, a piezoelectric layer 1020 is deposited over the first conductive layer 1018. In block 914, as shown in FIG. 10C, the piezoelectric layer 1020 is patterned to include a resonator portion 1020a situated in the resonator region 1012a and a first passive portion 1020b situated in the first passive component region 1012b. In this example, the patterned piezoelectric layer 1020 also includes a second passive portion 1020c situated in the second passive component region 1012c, and a third passive portion 1020d situated in the third passive component region 1012d. In block 915, a first via 1022 is formed in the first passive portion 1020b, for instance, by etching, to partially expose a top surface of first passive portion 1018b of the first conductive layer. Similarly, a second via 1023 is formed in the second passive portion 1020c to partially expose a top surface of second passive portion 1018c of the first conductive layer.

In block 916 of FIG. 9, a second conductive layer 1024 is deposited over the piezoelectric layer 1020. In block 918, the second conductive layer 1024 is patterned to define a resonator portion 1024a situated in the resonator region 1012a, a first passive portion 1024b situated in the first via 1022 of the first passive component region 1012b and contacting the partially exposed top surface of first passive portion 1018b of the first conductive layer, a second passive portion 1024c situated in the second via 1023 of the second passive component region 1012c and contacting the partially exposed top surface of second passive portion 1018c of the first conductive layer, and a third passive portion 1024d situated in the third passive component region 1012d, as shown in FIG. 10D.

In block 920 of FIG. 9, a third conductive layer 1026 is deposited over the second conductive layer 1024. In block 922, as shown in FIG. 10E, the third conductive layer 1026 is patterned to include a first passive portion 1026a situated in the first passive component region 1012b and in conductive contact with the first passive portion 1024b of the second conductive layer, and a second passive portion 1026b situated in the second passive component region 1012c and coupled to the second passive portion 1024c of the second conductive layer. In block 922 of FIG. 9, the SAC layer 1004 is removed. The resonator portions of the remaining layers define a piezoelectric resonator structure 1030, as shown in FIG. 10F. This structure 1030 at least partially overlays a first gap 1032 defined by removal of SAC layer portion 1004a. The first passive portions of the remaining layers define a passive circuit component structure 1034, which at least partially overlays a second gap 1036 defined by removal of SAC layer portion 1004b. In some implementations, for instance, when the first passive component in region 1012b is an inductor, the first passive portion 1026a is sufficiently thick to provide high Q and low resistivity. In such instances, the piezoelectric portion 1020b should generally be sufficiently thick to isolate the third conductive layer from the first conductive layer. When the piezoelectric layer is formed of AlN, thermal dissipation can be achieved in high power amplifier and other circuits incorporating the inductor.

FIG. 10G shows an example of a top-down view of a combined resonator and passive circuit component device, for instance, as represented in FIG. 10F. The device of FIG. 10G represents one of many examples of the resulting device of the process of FIG. 9. In one example, the cross-sectional view of FIG. 10F is taken along lines 10E-10F of the device of FIG. 10G. In FIG. 10G, the resonator portion 1024a of the second conductive layer is patterned in the form of two or more elongated electrodes 1054 overlaying portion 1020a of the piezoelectric layer, to define a piezoelectric laterally vibrating resonator in region 1012a.

The first passive portion 1026a of the third conductive layer is shaped in a spiral pattern as shown in FIG. 10G, and includes a first terminal 1058 and a second terminal 1062. One of these terminals can be implemented in FIG. 10F as the first conductive layer portion 1018b coupled to the spiral pattern of portion 1026a of the third conductive layer by virtue of portion 1024b of the second conductive layer disposed in via 1022. The other terminal can be situated in the third conductive layer 1026 as generally shown in FIG. 10F. The resulting two-terminal device in region 1012b is an inductor, in this example.

In FIG. 10G, the conductive material of portions 1026b, 1024c and 1018c in region 1012c can serve as a resistor in some examples. The amount of conductive material in portions 1026b, 1024c and 1018c can be set to control the resistance of such a resistor. The resulting two-terminal device in region 1012d is a capacitor in this example, with portion 1024d serving as a first conductive plate, piezoelectric portion 1020d serving as a dielectric layer, and portion 1018d serving as a second conductive plate.

In FIG. 10F and FIG. 10G, additional portions of the above-described conductive layer(s) can be formed on substrate 1008 to define electrodes for routing signals to the resonator and/or any of the passive circuit components. Such electrodes also can serve as conductive contacts with external circuitry or as probing pads for evaluation of circuit performance. For instance, the resistor structure in region 1012c can serve as such an electrode, since the third conductive layer portion 1026b is coupled to the first conductive layer portion 1018c by virtue of second conductive layer portion 1024c in via 1023. Thus, inter-layer electrical connections can be realized for various circuit implementations.

The piezoelectric materials that can be used in fabrication of the piezoelectric layers of electromechanical systems resonators and dielectric layers of passive components disclosed herein include, for example, aluminum nitride (AlN), zinc oxide (ZnO), gallium arsenide (GaAs), aluminum gallium arsenide (AlGaAs), gallium nitride (GaN), quartz and other piezoelectric materials such as zinc-sulfide (ZnS), cadmium-sulfide (CdS), lithium tantalite (LiTaO3), lithium niobate (LiNbO3), lead zirconate titanate (PZT), members of the lead lanthanum zirconate titanate (PLZT) family, doped aluminum nitride (AlN:Sc), and combinations thereof. The conductive layers described above may be made of various conductive materials including platinum (Pt), aluminum (Al), molybdenum (Mo), tungsten (W), titanium (Ti), niobium (Nb), ruthenium (Ru), chromium (Cr), doped polycrystalline silicon, doped aluminum gallium arsenide (AlGaAs) compounds, gold (Au), copper (Cu), silver (Ag), tantalum (Ta), cobalt (Co), nickel (Ni), palladium (Pd), silicon germanium (SiGe), doped conductive zinc oxide (ZnO), and combinations thereof. In various implementations, the upper metal electrodes and/or the lower metal electrodes can include the same conductive material(s) or different conductive materials.

The description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

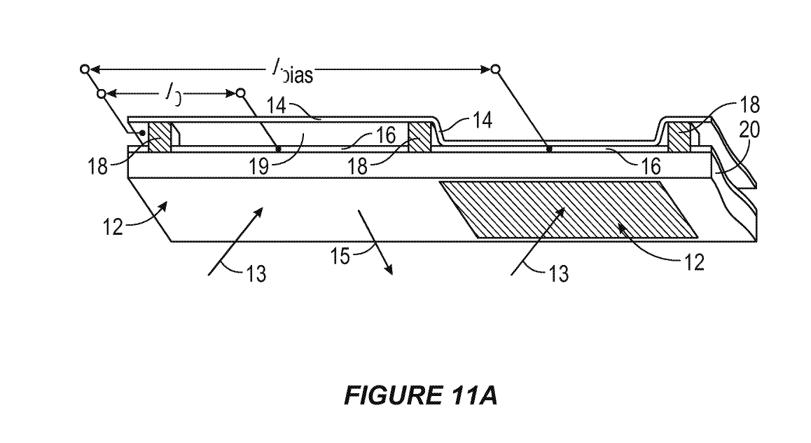

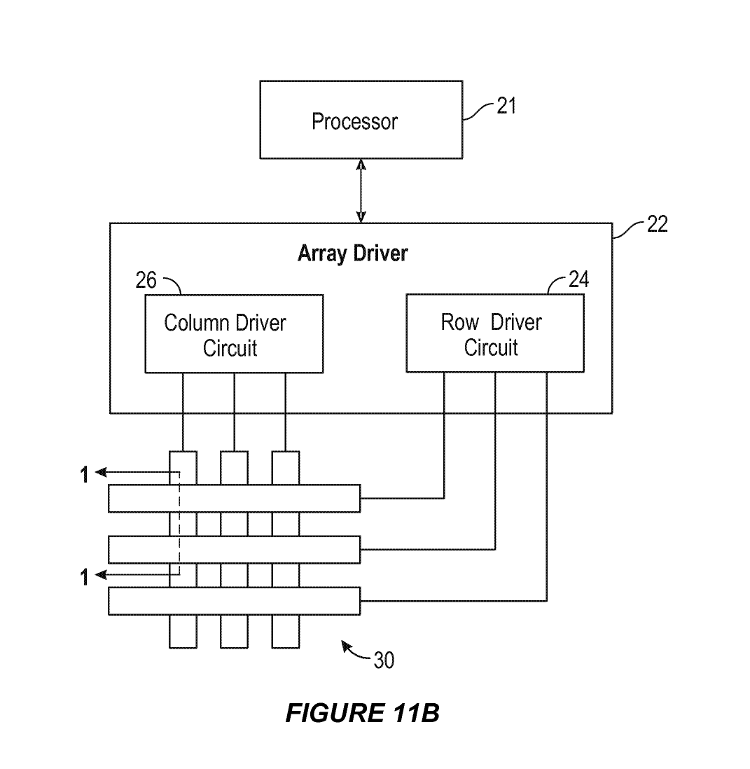

FIG. 11A is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 11A includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 11A, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 11A and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (A).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 11A, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 11A. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 11B is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 11A is shown by the lines 1-1 in FIG. 11B. Although FIG. 11B illustrates a 3×3 array of IMOD display elements for the sake of clarity, the display array 30 may contain a very large number of IMOD display elements, and may have a different number of IMOD display elements in rows than in columns, and vice versa.

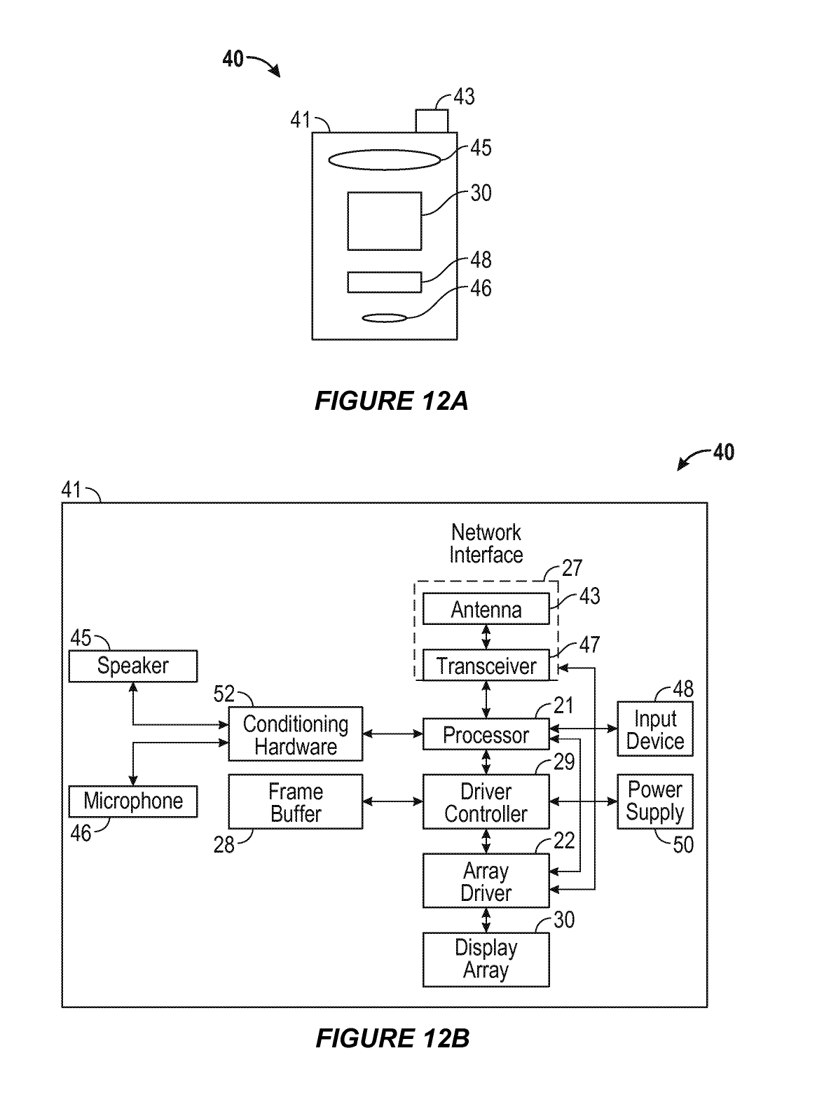

FIGS. 12A and 12B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 12A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 12A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
one or more inductor-capacitor (LC) resonant circuit stages, each LC stage including an inductor and a capacitor, each LC stage having a corresponding resonant frequency, the one or more LC stages being arranged to produce an unmodified passband over a range of frequencies having a corresponding bandwidth; and
one or more microelectromechanical systems (MEMS) resonators, the one or more MEMS resonators being arranged with the one or more LC stages so as to modify characteristics of the unmodified passband so as to produce a modified passband having a modified bandwidth and one or more other modified band characteristics.

2. The device of claim 1, wherein the one or more other modified band characteristics include sharper roll-off at one or more edges of the modified passband.

3. The device of claim 1, wherein the one or more other modified band characteristics include a smaller shape factor relative to the unmodified passband.

4. The device of claim 1, wherein the one or more other modified band characteristics include a notch or stopband in a portion of the frequencies in the range of frequencies corresponding to the unmodified passband.

5. The device of claim 1, wherein the modified bandwidth is a narrower bandwidth than the unmodified bandwidth.

6. The device of claim 1, wherein the modified passband has a larger fractional bandwidth than the unmodified passband.

7. The device of claim 1, wherein the one or more LC stages include two or more series LC stages arranged in series with one another.

8. The device of claim 7, wherein the one or more MEMS resonators include one or more shunt MEMS resonators each arranged to shunt current between a set of two adjacent series LC stages to ground.

9. The device of claim 8, wherein:
the one or more LC stages include one or more shunt LC stages each arranged between two adjacent series LC stages and arranged to shunt current between the two series LC stages to ground; and
one or more of the shunt MEMS resonators are arranged in parallel with one or more of the shunt LC stages.

10. The device of claim 9, wherein the one or more MEMS resonators include one or more series MEMS resonators each arranged in series with one another or with one or more of the series LC stages.

11. The device of claim 10, further including at least one shunt MEMS resonator arranged to shunt current between a series LC stage and a series MEMS resonator to ground.

12. The device of claim 1, wherein the one or more MEMS resonators include two or more series MEMS resonators arranged in series with one another.

13. The device of claim 12, wherein the one or more MEMS resonators include one or more shunt MEMS resonators each arranged to shunt current between a set of two adjacent MEMS resonators to ground.

14. The device of claim 13, wherein:
the one or more LC stages include one or more shunt LC stages each arranged to shunt current between a set of two adjacent series MEMS resonators to ground; and
one or more of the shunt MEMS resonators are arranged in parallel with one or more of the shunt LC stages.

15. The device of claim 14, wherein the one or more LC stages include one or more series LC stages each arranged in series with one another or with one or more of the series MEMS resonators.

16. The device of claim 15, further including at least one shunt MEMS resonator arranged to shunt current between a series LC stage and a series MEMS resonator to ground.

17. The device of claim 1, wherein one or more of the MEMS resonators have different resonant frequencies than other ones of the MEMS resonators.

18. The device of claim 1, wherein one or more of the MEMS resonators are elastic or acoustic resonators.

19. The device of claim 18, wherein one or more of the MEMS resonators are contour-mode resonators.

20. The device of claim 18, wherein one or more of the MEMS resonators are thin film bulk acoustic resonators (FBARs).

21. The device of claim 1, wherein the LC stages and the MEMS resonators are fabricated on a single substrate.

22. A device comprising:
one or more inductor-capacitor (LC) resonating means, each LC resonating means including an inducting means and a capacitive means, each LC resonating means having a corresponding resonant frequency, the one or more LC resonating means being arranged to produce an unmodified passband over a range of frequencies having a corresponding bandwidth; and
one or more microelectromechanical systems (MEMS)-based resonating means, the one or more MEMS-based resonating means being arranged with the one or more LC resonating means so as to modify characteristics of the unmodified passband so as to produce a modified passband having a modified bandwidth and one or more other modified band characteristics.

23. The device of claim 22, wherein the one or more MEMS-based resonating means include two or more series MEMS-based resonating means arranged in series with one another or with an LC resonating means.

24. The device of claim 22, wherein the one or more MEMS-based resonating means include one or more shunt MEMS-based resonating means each arranged to shunt current between two MEMS-based resonating means or between two LC resonating means or between a MEMS-based resonating means and an LC resonating means.

25. The device of claim 22, wherein the LC resonating means and the MEMS-based resonating means are fabricated on a single substrate.

26. The device of claim 22, wherein the modified passband has a larger fractional bandwidth than the unmodified passband.
